(19) United States
(12) Patent Application Publication
(10) Pub. No.: US 2022/0157657 A1
(43) Pub. Date: May 19, 2022

(54) SINGULATING INDIVIDUAL CHIPS FROM WAFERS HAVING SMALL CHIPS AND SMALL SEPARATION CHANNELS

(71) Applicant: International Business Machines Corporation, Armonk, NY (US)

(72) Inventors: Cyril Cabral, JR., Yorktown Heights, NY (US); Frank Robert Libsch, White Plains, NY (US); Chitra Subramanian, Mahopac, NY (US); Peter Jerome Sorce, Poughkeepsie, NY (US); Paul Alfred Lauro, Brewster, NY (US); John M. Papalia, New York, NY (US)

(21) Appl. No.: 17/097,113

(22) Filed: Nov. 13, 2020

(51) Int. Cl. H01L 21/78; H01L 21/3065; H01L 21/67

(52) U.S. Cl. CPC H01L 21/78; H01L 21/67069; H01L 21/3065

(57) ABSTRACT

Embodiments of the invention include a method of singulating IC chips from a wafer. The method can include receiving the wafer having a substrate formed under active layers. The wafer includes a chip that includes a first portion of the active layers and a first portion of the substrate. A separation trench is formed by using an etch operation to remove a first segment of the active layers and a first segment of the substrate that are beneath a first separation channel of the wafer. The separation trench separates the first portion of the active layers from a remaining portion of the active layers; and separates the first portion of the substrate from a remaining portion of the substrate. The first IC chip is seperated from the wafer by removing a first section of the remaining portion of the substrate that is underneath the first portion of the substrate.

### BACKGROUND

The present invention relates in general to the fabrication and packaging of integrated circuits (ICs) formed on portions of a semiconductor wafers. More specifically, the present invention relates to fabrication systems and fabrication methods for singulating (i.e., removing) individual IC chips (or semiconductor die) from wafers, wherein the IC chips are separated from one another on the semiconductor wafer by relatively small chip separation channel widths (e.g., less than about 20 μm).

Semiconductor wafers are fabricated in a series of stages, including a front-end-of-line (FEOL) stage, a middle-of-line (MOL) stage and a back-end-of-line (BEOL) stage. The process flows for fabricating modern semiconductor wafers are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The FEOL stage processes also involve the formation of a plurality of IC chips or semiconductor die on the surface of a semiconductor wafer. Each IC chip contains circuits formed by electrically connecting active and passive components. The MOL stage typically includes process flows for forming interconnect structures (e.g., lines, wires, metal-filled vias, contacts, and the like) that communicatively couple to active regions (e.g., gate, source, and drain) of the device element. During the BEOL stage, layers of interconnect structures are formed above these logical and functional layers to complete the semiconductor wafer. Most semiconductor wafers need more than one layer of interconnects to form all the necessary connections, and as many as 5-12 layers are added in the BEOL process.

BEOL processes can also include singulating (or removing) individual IC chips from the finished semiconductor wafer and packaging the IC chip(s) to provide structural support and environmental isolation. Although the size of individual IC chips continues to decrease with the proliferation of small or miniaturized mobile computing systems, known methods of singulating IC chips from finished semiconductor wafers have shortcomings when applied to semiconductor wafers having relatively small IC chips and relatively small chip separation channels. For example, a singulation process known as dicing uses a water-cooled rotating disk to cut through the chip separation channels to singulate the individual IC chips of the semiconductor wafers. Because dicing involves a rotating disk (e.g. metal, polymer, diamond, etc.), the chip separation channel must be relatively wide, typically greater than about 50 μm, and more typically about 100 μm. The need to devote significant portions of the semiconductor floor plan to chip separation channels reduces the number of IC chips that can be formed on a given semiconductor wafer. Additionally, the rotating disk used in dicing processes results in increased perimeter roughness (e.g., generally greater than 10 μm Ra) of the singulated IC chip. The assembly tools that align singulated IC chips with their host motherboard during packaging use the perimeter edge of the IC chip as a reference point for properly aligning the solder posts of the IC chip with the bonding pads of the motherboard. When the perimeter edge of the IC chip is rough, assembly tools that use the perimeter edge of the IC chip as a reference point have difficulty properly aligning such IC chips with their host motherboard.

Laser ablation singulation processes use a laser to remove material in the chip separation channel to thereby singulate individual IC chips from a semiconductor wafer. Although laser ablation can provide better chip separation channel width and perimeter roughness performance than dicing, laser ablation singulation processes generate molten debris or slag that deposits on the surfaces of the semiconductor wafer, thereby damaging to-be-singulated IC chips. It is very difficult to protect the semiconductor wafer during laser ablation singulation processes because molten materials (e.g. metals, dielectrics, etc.) destroy any protective films that have been placed on the semiconductor wafer.

A singulation process known as “stealth dicing” uses a laser to make defects in the silicon substrate by scanning a laser beam along intended cutting lines. An underlying carrier membrane is then expanded to induce a fracture and in effect pull the IC chips away from the substrate. A shortcoming of known stealth dicing techniques is that for IC chip dimensions smaller than 0.5 mm, a phenomenon known as meanderance occurs, which results in the singulated IC chips having perimeter edge roughness that is sufficient to interfere with assembly tool alignment processes. Additionally, known stealth dicing techniques lack the necessary performance reliability and consistency because the substrate does not reliably and consistently separate, which results in IC chips remaining connected together, which further results in the requirement of additional processing in order to achieve singulation.

### SUMMARY

Embodiments of the invention are directed to a method of singulating integrated circuit (IC) chips from a host semiconductor wafer. In a non-limiting embodiment of the invention, the method includes receiving the host semiconductor wafer that includes a substrate and active layers formed over the substrate. The host semiconductor wafer further includes a first IC chip that includes a first portion of the active layers and a first portion of the substrate. A first separation trench is formed by using an etch operation to remove a first segment of the active layers and a first segment of the substrate that are beneath a first separation channel of the host semiconductor wafer. The first separation trench separates the first portion of the active layers from a remaining portion of the active layers, and also separates the first portion of the substrate from a remaining portion of the substrate. The first IC chip is singulated from the host semiconductor wafer by using a substrate removal operation to remove a first section of the remaining portion of the substrate that is underneath the first portion of the substrate.

Technical effects and benefits of the above-described embodiments of the invention include the use of etch operations to form the first separation trench, which enables the first separation trench to have feature resolution ranges (i.e., feature dimension ranges) that matches the feature resolution ranges of the etch operations. In accordance with aspects of the invention, the etch operations enable the formation of separation trenches having width dimension less than about 20 microns. In some embodiments of the invention, the etch operations enable the formation of separation trenches having width dimension between about 10 microns and about 20 microns.

The above-described embodiments of the invention can further include the first separation trench having a first segment and a second segment. The first segment of the first separation trench separates the first portion of the active layers from the remaining portion of the active layers. The second segment of the first separation trench separates the first portion of the substrate from the remaining portion of the substrate. The etch operation can include a first etch operation configured to form the first segment of the first separation trench, along with a second etch operation configured to form the second segment of the first separation trench. The active layers can include a front-end-of-line (FEOL) layer and a back-end-of-line (BEOL) layer. The first etch operation can include a sputter etch operation, and the second etch operation can include a directional reactive ion etch (RIE) operation. The substrate removal operation can include polishing the first section of the remaining portion of the substrate that is underneath the first portion of the substrate.

Additional technical effects and benefits of the above-described embodiments of the invention include the use of a sputter etch operations to form the first segment of the separation trenches. The sputter etch operations are configured to remove the multiple different types of materials (e.g., metals, dielectrics, doped semiconductors, etc.) in the FEOL and BEOL layers from which the active layers can be formed. The sputter etch operations are also configured to form smooth edges during removal of the multiple different types of materials (e.g., metals, dielectrics, doped semiconductors, etc.) in the FEOL and BEOL layers from which the active layers can be formed. The directional RIE operations are configured to directionally remove the semiconductor material (e.g., silicon) from which the substrate can be formed. The directional RIE operations are also configured to form smooth edges during removal of the semiconductor material (e.g., silicon) from which the substrate can be formed. The polishing operation used to remove the first section of the remaining portion of the substrate that is underneath the first portion of the substrate is configured to form smooth edges during the polishing operation. The smooth perimeter edges formed during the etch operations and the polishing operations improve the functioning of packaging tools that the rely on automatic detection of the perimeter edges of the IC chip in order to accurately align the IC chip with its support substrate (e.g., a motherboard) during packaging. In embodiments of the invention, the sputter etch operations, the directional etch operations, and the polishing operations result in the singulated IC chips having very smooth perimeter edges having a roughness level that is less than about 4 μm Ra.

The above-described embodiments of the invention can further include the host semiconductor wafer further including a second IC chip that includes a second portion of the active layers and a second portion of the substrate. A second separation trench can be formed by using the etch operation to, in parallel with the above-described removal of the first segment of the active layers and the first segment of the substrate, remove a second segment of the active layers; and remove a second segment of the substrate that are beneath a second separation channel of the host semiconductor wafer. The second separation trench separates the second portion of the active layers from the remaining portion of the active layers; and separates the second portion of the substrate from the remaining portion of the substrate. The second IC chip is singulated from the host semiconductor wafer by using the substrate removal operation to, in parallel with the above-described removal of the first section of the remaining portion of the substrate that is underneath the first portion of the substrate, removing a second section of the remaining portion of the substrate that is underneath the second portion of the substrate.

Additional technical effects and benefits of the above-described embodiments of the invention include the sputter etch operation being applied in parallel to all of the IC chips on the host semiconductor wafer; the directional RIE operation being applied in parallel to all of the IC chips on the host semiconductor wafer; and the substrate polishing operation being applied to all of the IC chips on the host semiconductor wafer. Applying the etch operations and polishing operation across all of the IC chips on the host semiconductor in parallel improves efficiency and saves cost over known singulation operations that are applied in series to each IC chip on the host semiconductor wafer.

The above-described embodiments of the invention can further include forming a photoresist layer on the host semiconductor wafer, wherein the photoresist layer defines the first separation channel and the second separation channel of the host semiconductor wafer. In some embodiments of the invention, the photoresist layer can have a predetermined thickness. In some embodiments of the invention, a hardening process can be applied to the photoresist layer.

Additional technical effects and benefits of the above-described embodiments of the invention include the hardening process and the predetermined thickness improving a resistance of the photoresist layer to damage caused by the etch operations (e.g., sputtering etch and direction RIE) used to remove the first segment of the active layers that are beneath the first separation channel of the host semiconductor wafer.

Embodiments of the invention are also directed to fabrication systems configured to implement the above-described fabrication methods and provide the above-described technical effects and benefits.

Additional features and advantages are realized through the techniques described herein. Other embodiments and aspects are described in detail herein. For a better understanding, refer to the description and to the drawings.

### BRIEF DESCRIPTION OF THE DRAWINGS

The subject matter which is regarded as the present invention is particularly pointed out and distinctly claimed in the claims at the conclusion of the specification. The foregoing and other features and advantages are apparent from the following detailed description taken in conjunction with the accompanying drawings in which:

FIG. 1 depicts a flow diagram illustrating a methodology according to embodiments of the invention;

FIG. 2 depicts a top-down view of a semiconductor wafer after initial singulation operations according to embodiments of the invention;

FIG. 3A depicts a top-down view and a cross-sectional view of a semiconductor wafer after additional singulation operations according to embodiments of the invention;

FIG. 3B depicts a cross-sectional view of a semiconductor wafer after additional singulation operations according to embodiments of the invention, along with a block diagram illustrating a sputter etch process that can be used in accordance with embodiments of the invention to the perform the additional singulation operations that result in the cross-sectional view of the semiconductor wafer;

FIG. 4A depicts a top-down view and a cross-sectional view of a semiconductor wafer after additional singulation operations according to embodiments of the invention;

FIG. 4B depicts a primary cross-sectional view of a semiconductor wafer after additional singulation operations according to embodiments of the invention, along with secondary cross-sectional views of a semiconductor wafer after a so-called Bosch directional reactive ion etch (RIE) process that can be used in accordance with embodiments of the invention to the perform the additional singulation operations that result in the primary cross-sectional view of the semiconductor wafer;

FIG. 5 depicts a bottom-up view and a cross-sectional view of a semiconductor wafer after additional singulation operations according to embodiments of the invention;

FIG. 6 depicts a bottom-up view and a cross-sectional view of a semiconductor wafer after additional singulation operations according to embodiments of the invention;

FIG. 7 depicts top-down views of singulated IC chips after completion of singulation operations according to embodiments of the invention;

FIG. 8 depicts top-down views of the singulated IC chips shown in FIG. 7 after mounting the singulated IC chips to a motherboard as part of as set of final packaging operations; and

FIG. 9 depicts a configuration of semiconductor fabrication systems capable of implementing embodiments of the invention.

In the accompanying figures and following detailed description of the disclosed embodiments, the various elements illustrated in the figures are provided with three or four digit reference numbers.

### DETAILED DESCRIPTION

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

The terms “separation channel,” “chip separation channel,” “chip separation channel pattern,” “dicing channel,” and equivalents thereof are used herein to define the two-dimensional (2D) areas of a semiconductor wafer surface that define the top-down 2D area of a three-dimensional (3D) “separation channel,” “chip separation channel,” and/or “chip separation channel pattern” that will be formed in the semiconductor wafer to separate IC chips formed on the wafer from one another.

The terms “separation trench,” “chip separation trench,” “chip separation trench pattern,” and equivalents thereof are used herein to define 3D trenches formed in a semiconductor wafer to separate IC chips formed on the wafer from one another.

The terms “lithography,” “photolithograph,” and equivalents thereof are used herein to identify a process of transferring patterns of geometric shapes in a mask to a layer of radiation-sensitive material (called resist or photoresist) covering the surface of a semiconductor wafer. Radiation is transmitted through clear parts of the mask and makes the exposed photoresist either soluble or insoluble in the developer solution, thereby enabling the direct transfer of the mask pattern onto the wafer. After the patterns are defined, an etching process is employed to selectively remove masked portions of the underlying layer.

The terms “resolution,” “mask resolution,” “pattern resolution,” “feature resolution,” and equivalents thereof are used herein to identify the minimum feature dimension(s) that can be transferred with high fidelity to a photoresist film on a semiconductor wafer in the form of a photoresist film pattern (or openings).

Turning now to an overview of aspects of the present invention, embodiments of the invention provide fabrication systems and fabrication methods for singulating (i.e., removing) individual IC chips (or semiconductor die) from their host semiconductor wafer, wherein the host semiconductor wafer includes various BEOL and FEOL layers on the wafer substrate (e.g., silicon). In some embodiments of the invention, the BEOL layers can include Far-BEOL layers, and the FEOL layers can include MOL layers. The IC chips are separated from one another on the host semiconductor wafer by chip separation channels. The separation channels define the footprints of to-be-formed separation trenches having relatively small width dimensions (e.g., less than about 20 μm). Instead of relying on known dicing, stealth dicing, and/or laser ablation singulation techniques, embodiments of the invention utilize a novel arrangement of etching and polishing operations to singulate IC chips from their host semiconductor wafer. In accordance with aspects of the invention, the IC chips are separated from one another by defining chip separation channels on the host semiconductor wafer surface then etching through the separation channels and the various Far-BEOL, BEOL, MOL, and/or FEOL layers on the semiconductor wafer to form initial separation trenches that stop on the host semiconductor wafer substrate.

At this stage of the novel singulation process, the initial separation trenches separate the individual IC chips from one another at the Far-BEOL, BEOL, MOL, and/or FEOL levels, but each individual IC chip's Far-BEOL, BEOL, MOL, and/or FEOL levels are still attached at separate locations on the underlying substrate of the host semiconductor wafer. In accordance with aspects of the invention, the bottom surface of each initial separation trench is an exposed portion of the underlying substrate. The initial separation trenches are extended a predetermined distance into the substrate by applying a directional etch to the exposed portion of the underlying substrate within the initial separation trenches, thereby forming extension separation trenches. The extension separation trenches define individual chip substrates of the individual IC chips, wherein each individual chip substrate is coupled at one end to one of the IC chip's Far-BEOL, BEOL, MOL, and/or FEOL levels, and coupled at an opposing end to a bottom section of the underlying semiconductor wafer substrate that remains after the extension separation trench is formed. To release the individual IC chips (including the IC chip substrates) from the remaining bottom section of the semiconductor wafer substrate, the remaining bottom section of the wafer substrate is removed to open the bottom ends of the extension separation trenches, thereby releasing each individual IC chip (including the IC chip substrate) from the remaining bottom section of the wafer substrate. In embodiments of the invention, at least the later stages of the process used to remove the remaining bottom section of the wafer substrate is a fine polishing process

In embodiments of the invention, the initial etch operation used to form the initial separation trenches is configured and arranged to etch through the various materials from which the Far-BEOL, BEOL, MOL, and/or FEOL layers are formed (e.g., metals, dielectrics, doped semiconductor materials, etc.). In some embodiments of the invention, the initial etch operation is a sputter etch operation. In some embodiments of the invention, the sputter etch operation uses argon as the bombardment ions. In some embodiments of the invention, the directional etch operation used to form the extension separation trenches is a directional reactive ion etch (RIE). In some embodiments of the invention, the directional RIE operation used to form the extension separation trenches is a so-called “Bosch” directional RIE operation. In embodiments of the invention, the Bosch directional RIE process is a high-aspect ratio plasma etching process that uses quick gas switching to cycle between isotropic etching and fluorocarbon-based protection film deposition. The SF₆ plasma cycle etches the substrate material (e.g., silicon), and the C₄F₈ plasma cycle creates a protection layer. In embodiments of the invention, the SF₆ plasma cycle and the C₄F₈ plasma cycle are optimized to achieve deep silicon etching with high aspect ratios.

The use of patterned lithography and etch operations to form the separation trenches enable the separation trench to have shapes and feature resolution ranges (i.e., feature dimension ranges) that match the shapes and feature resolution ranges of the patterned lithograph and etch operations. In accordance with aspects of the invention, the patterned lithography and etch operations enable the formation of separation trenches having width dimension less than about 20 microns. In some embodiments of the invention, the patterned lithograph and etch operations enable the formation of separation trenches having width dimension between about 10 microns and about 20 microns. In embodiments of the invention, the patterned lithography and etch operations enable the formation of separation trenches having a wide variety of shapes, including but not limited to circles, squares, rectangles, hexagons, octagons, serpentine, and combinations thereof.

The sputter etch, directional RIE, and polishing processes used in the disclosed novel singulation process result in the singulated IC chips (including the IC chip substrates) having very smooth perimeter edges having a roughness level that is less than about 4 μm Ra. The smooth perimeter edges formed in accordance with aspects of the invention improve the functioning of packaging tools that the rely on automatic detection of the perimeter edges of the IC chip in order to accurately align the IC chip with its support substrate (e.g., a motherboard) during packaging. The sputter etch, directional RIE, and polishing processes used in the disclosed novel singulation process also do not generate debris (e.g., molten debris or slag) that deposits on the surfaces of the semiconductor wafer, thereby damaging to-be-singulated IC chips.

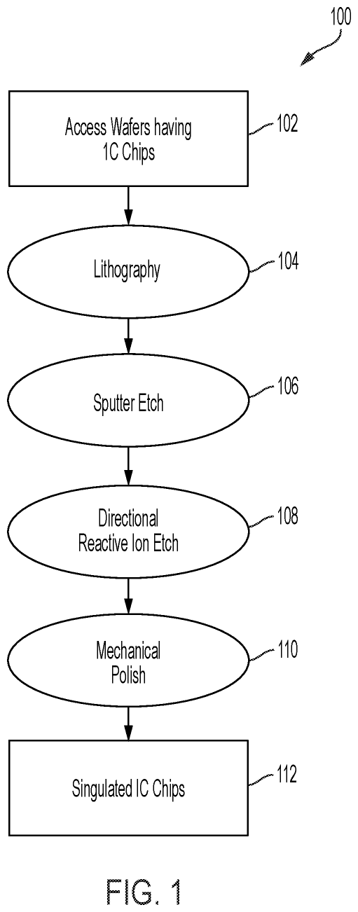

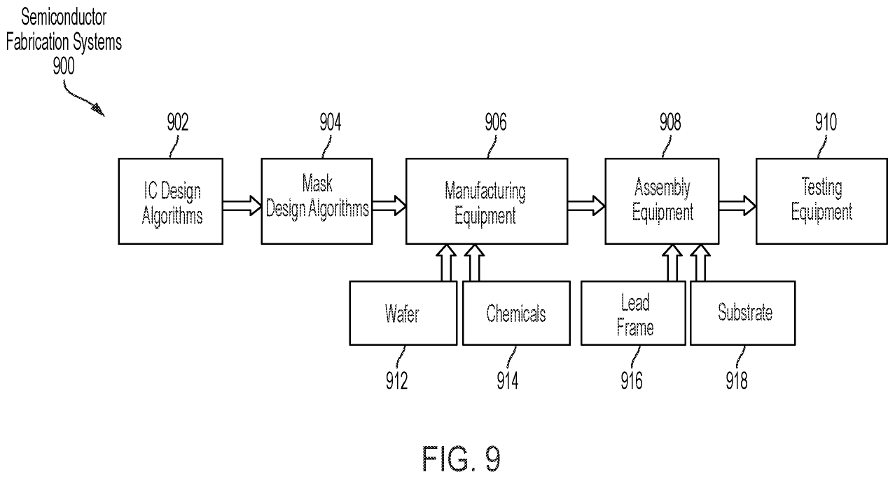

Turning now to a more detailed description of aspects of the present invention, FIG. 1 depicts a flow diagram illustrating a chip singulation method 100 according to embodiments of the invention. The method 100 can be implemented using a variety of known types and configurations of semiconductor fabrication equipment. An example semiconductor fabrication system 900 capable of implementing aspects of the invention is depicted in FIG. 9 and described in greater detail subsequently herein. For the sake of brevity, conventional fabrication systems or equipment related to performing aspects of the invention may or may not be described in detail herein. In particular, various aspects of fabrication systems used to implement the various technical features described herein are well known. Accordingly, in the interest of brevity, many conventional details of such fabrication systems/equipment are only mentioned briefly herein or are omitted entirely without providing the well-known system/equipment details.

In accordance with embodiments of the invention, the method 100 includes at block 102 accessing wafers having IC chips formed thereon. At block 104, a lithography process is used to apply a layer of light-sensitive material known as photoresist over the wafer. A laser light source is cast onto the photoresist to create patterns (or openings) that define the location, size, and shape of separation channels that define the location, size, and shape of separation trenches that will be formed under the separation channels. Because the light source can directly define patterns on the photoresist that are as small as the light's wavelength, very small pattern resolutions can be achieved with the lithography operations performed at block 104 by exposing the photoresist to light having a relatively small wavelength. In some embodiments of the invention, the lithography performed at block 104 can be an extreme ultra-violet (EUV) lithography that uses a light source with an EUV wavelength (e.g., about 13.5 nanometer wavelength) to define the photoresist pattern. In accordance with aspects of the invention, the photoresist pattern applied at block 104 and the etch operations applied at blocks 106, 108 enable the formation of separation channels/trenches having width dimension less than about 20 microns. In some embodiments of the invention, the photoresist pattern applied at block 104 and the etch operations applied at blocks 106, 108 enable the formation of separation channels/trenches having width dimension between about 10 microns and about 20 microns. In some embodiments of the invention, the photoresist pattern applied at block 104 and the etch operations applied at blocks 106, 108 enable the formation of separation trenches having a wide variety of shapes, including but not limited to circular, square, rectangular, hexagonal, serpentine, and combinations thereof.

In some embodiments of the invention, the method 100 uses the two etch operations performed at blocks 106, 108 to form the separation trenches. The first etch operation performed at block 106 is a sputter etch operation. The sputter etch at block 106 forms first segments of the separation trenches, wherein the first segment of each separation trench separates the portions of the FEOL and BEOL layers of the wafer that are part of a given IC chip from the FEOL and BEOL layers that are not part of the given IC chip. The sputter etch is a directional etch configured (e.g., through selection of the bombardment ions) to effectively etch through the multiple different types of materials (e.g., metals, dielectrics, doped semiconductors, etc.) in the FEOL and BEOL layers of the wafer. In accordance with aspects of the invention, the sputter etch also results in smooth surfaces and smooth perimeter edges within the first segment of the separation trench.

At this stage of the method 100, in accordance with aspects of the invention, the bottom surface of the first segments of each chip separation trench is an exposed portion of the underlying substrate. The second etch operation performed at block 108 is a directional reactive ion etch (RIE) operation that forms second segments of the separation trenches by directionally etching through the exposed portions of the wafer substrate that form the bottom surface of the separation trenches. Accordingly, the directional RIE partially segments sections of the wafer substrate so that the segmented wafer substrates function as the individual IC chip substrates. The directional RIE operations are also configured to form smooth edges during removal of the substrate material (e.g., silicon) that is below the first segments of the separation trenches. After using the etch operations at blocks 106, 108 to form the first and second segments of the separation trenches, all of the surfaces that form the individual IC chips have been separated from the rest of the wafer except a bottom of each IC chip substrate is still coupled to the remaining portion of the underlying wafer substrate.

At this stage of the method 100, the individual IC chip substrates are each coupled at one end to one of the IC chips and are coupled at an opposing end to the remaining portion of the underlying wafer substrate. To release the individual IC chips and their IC chip substrates from the remaining portion of the underlying wafer substrate, the mechanical polish operation shown at block 110 is performed. The mechanical polish operation at block 110 removes the remaining portion of the underlying wafer substrate to open the bottom end of the extended chip separation trenches, thereby generating at block 112 the singulated individual IC chips, wherein each IC chip includes its own FEOL/BEOL layers and substrate. In embodiments of the invention, at least the later stages of the mechanical polish performed at block 110 is includes a fine polishing process, which results in the singulated IC chips having IC chip substrates with very smooth perimeter edges. In embodiments of the invention, the IC chip substrate perimeter edges that result from the mechanical polish operation at block 110 each includes a roughness level that is less than about 4 μm Ra.

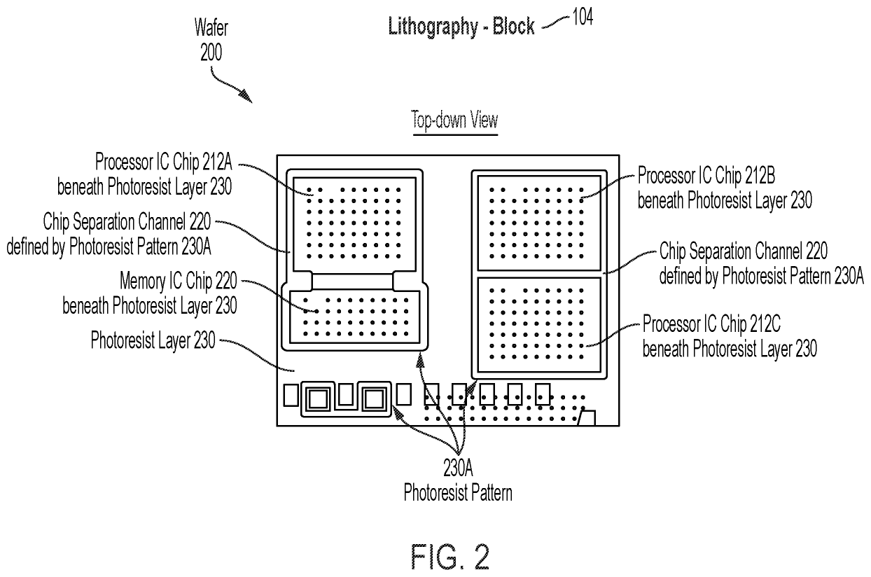

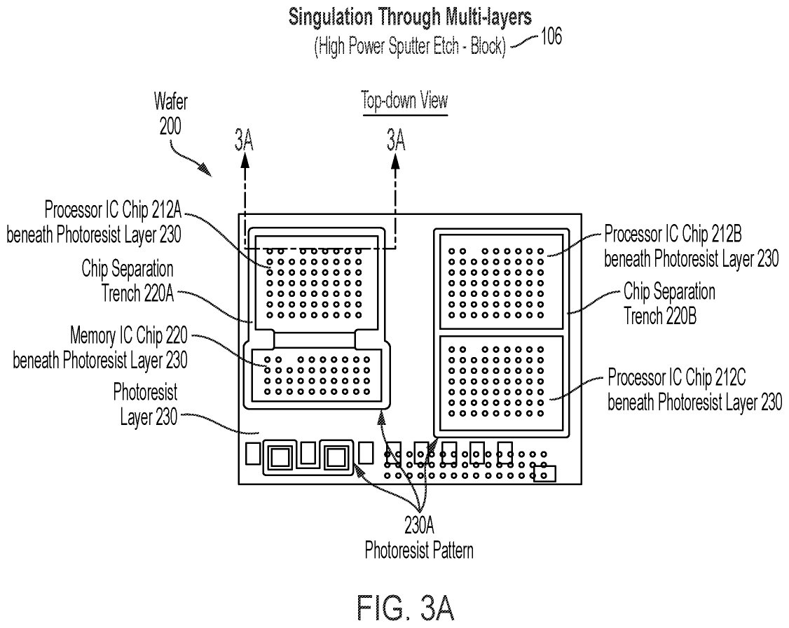

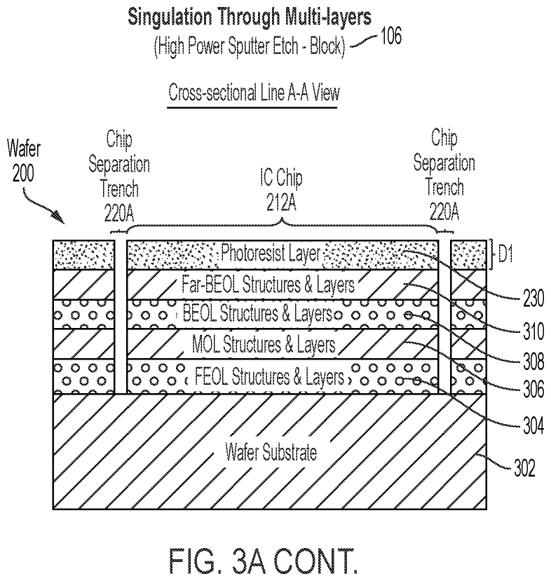

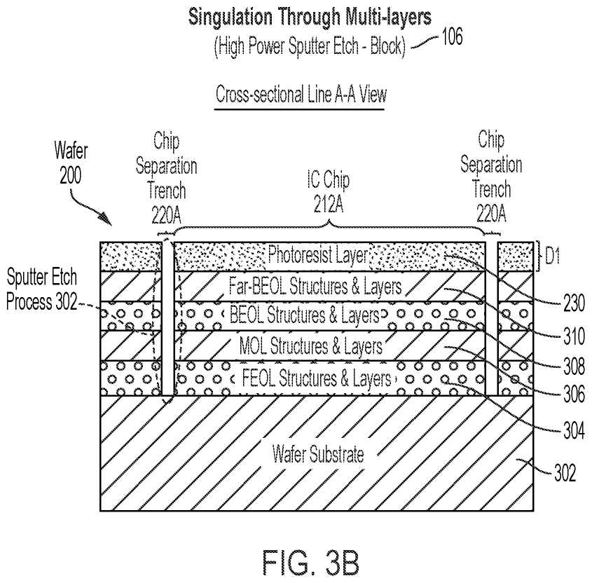

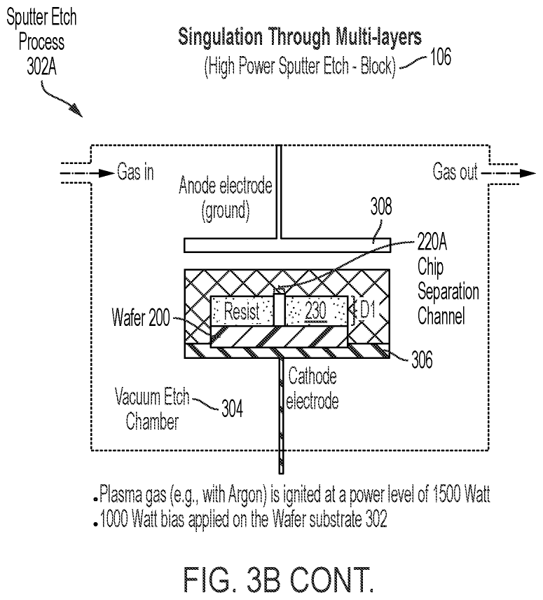

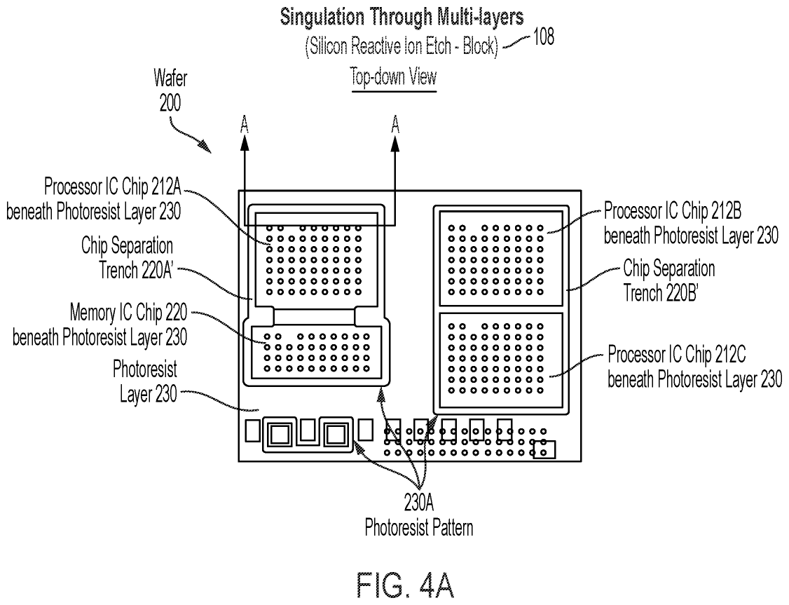

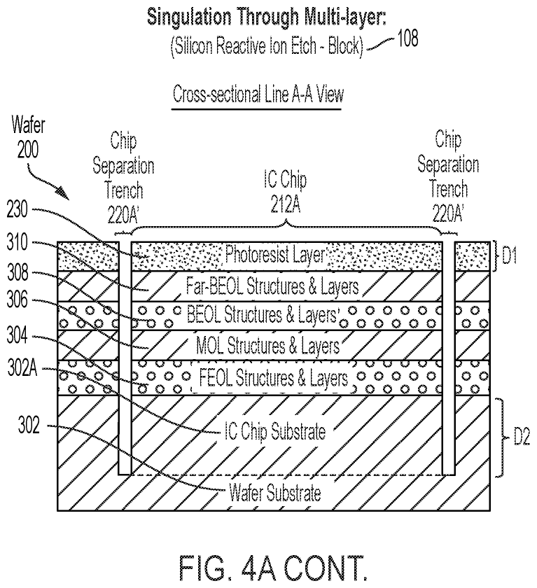

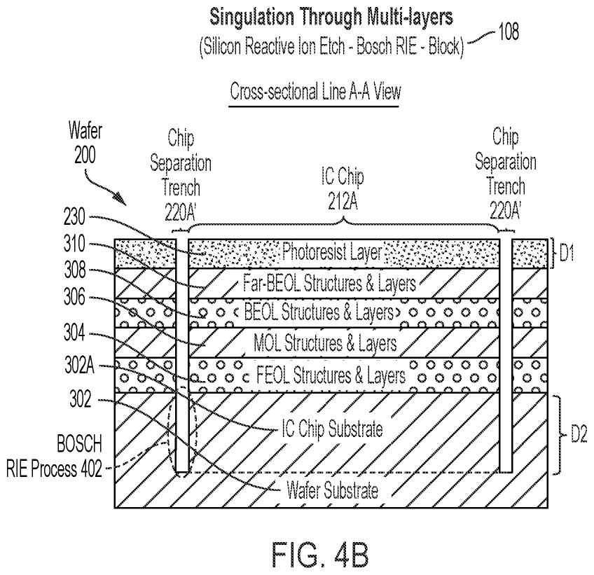

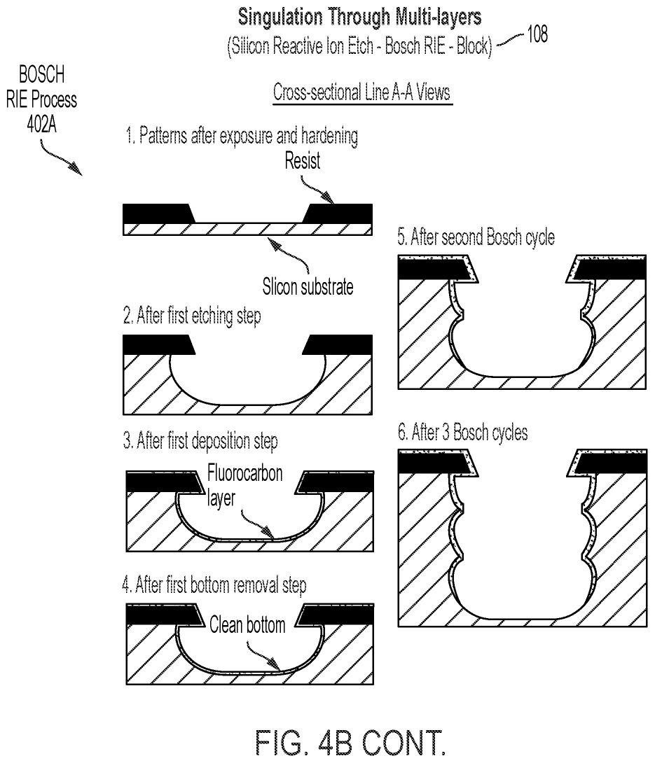

Additional details of how the operations of the method 100 can be implemented in accordance with aspects of the invention are depicted in FIGS. 2-7 and described in greater detail subsequently herein. Turning first to FIG. 2, a simplified top-down view of a wafer 200 is shown after a photoresist layer 230 has been deposited over a top major surface of the wafer 200 and patterned to create a photoresist pattern 230A. The photoresist pattern 230A defines chip separation channels 220 on the major surface of the wafer 200. The chip separation channels 220 define the footprint of chip separation trenches 220A, 220A′ (shown in FIGS. 3A, 3B, 4A, 4B) that will be formed by etching through the exposed portions of the wafer 200 defined by the chip separation channels 220. In the top-down view shown in FIG. 2, the chip separation channels 220 surround various IC chips 212A, 214, 212B, 212C that are positioned beneath the photoresist layer 230. In embodiments of the invention, the IC chips shown in FIG. 2 include a processor IC chip 212A combined with a memory IC chip 214; a processor IC chip 212B; and a processor IC chip 212C. For ease of illustration, three IC chips (212A in combination with 214; 212B; and 212C) are shown, any number of IC chips can be provided. Additionally, the shapes and contours of the photoresist pattern 230A in the top-down view can be any shape and/or contour that can be formed in a photoresist layer, including but not limited to squares, rectangles, circles, ovals, octagons, hexagons, triangles, straight lines, ellipses, and combinations thereof.

In embodiments of the invention, the photoresist layer 230 can be a positive photoresist and/or a negative photoresist. With positive photoresist, UV light strategically hits the material in the areas that the semiconductor supplier intends to remove. When the photoresist is exposed to the UV light, the chemical structure changes and becomes more soluble in the photoresist developer. These exposed areas are then washed away with the photoresist developer solvent, leaving the underlying material. The areas of the photoresist that aren't exposed to the UV light are left insoluble to the photoresist developer, which means that, after exposure, an identical copy of the pattern is left as a mask on the wafer. With negative photoresist, exposure to UV light causes the chemical structure of the photoresist to polymerize, which is the opposite of how positive photoresist reacts to UV light. Instead of becoming more soluble, negative photoresist becomes extremely difficult to dissolve. As a result, the UV exposed negative photoresist remains on the surface while the photoresist developer solution works to remove the areas that are unexposed. This leaves a mask that consists of an inverse pattern of the original, which is applied on the wafer. In the embodiments of the invention depicted herein, the photoresist layer 230 can be a negative photoresist, which can have intrinsic advantages for patterning narrow trench geometries.

In embodiments of the invention, the photoresist layer 230 is made sufficiently robust to withstand the sputter etch and directional RIE processes performed at blocks 106, 108. In aspects of the invention, the photoresist layer 230 is made robust by providing the photoresist layer 230 with sufficient thickness D1 and hardening to withstand the sputter etch and directional RIE processes performed at blocks 106, 108. Accordingly, the photoresist layer 230 can be provided with a predetermined thickness D1 (shown in FIG. 3A) and hardened using a suitable photoresist hardening process, including but not limited to hardening processes that utilize exposure of the photoresist layer 230 to ultra-violet (UV) light and subsequent baking. In embodiments of the invention, the photoresist layer 230 can be formed by spinning on a hexamethyldisilazane (HMDS) adhesion promoter then hot plate baking; spinning on then oven baking a negative photoresist (e.g., negative photoresist sold commercially by JSR) until D1 (shown in FIG. 3A) is about 50 μm thick; exposing the photoresist 230 (e.g., using a SUS MicroTec's MA-8 contact aligner) and develop; and post-exposure UV curing and oven baking to harden the photoresist layer 230. The resulting photoresist pattern 230A of the photoresist layer 230 can define separation channels 220 having widths that are about 20 μm or less in width.

FIG. 3A depicts a top-down view and a cross-sectional view of the semiconductor wafer 200 after applying an example of the sputter etch operations performed at block 106 of the method 100 according to embodiments of the invention. The top-down view of the wafer 200 shown in FIG. 3A is substantially the same as the top-down view of the wafer 200 shown in FIG. 2 except the example sputter etch operation has been applied to the wafer 200 to etch through the separation channels 220 (shown in FIG. 2) to form chip separation trenches 220A, 220B. For ease of illustration, the cross-sectional view of the semiconductor wafer 200 shown in FIG. 3A is taken along line A-A of the top-down view shown in FIG. 3A to isolate the IC chip 212A. However, it is understood that the fabrication operations shown in the cross-sectional line A-A views depicted in the figures apply equally to all of the IC chips (e.g., 214, 212B, 212C) formed in/on the wafer 200. As shown in the cross-sectional view of FIG. 3A, the wafer 200 includes a wafer substrate 302; FEOL structures and layers 304; MOL structures and layers 306; BEOL structures and layers 308; and Far-BEOL structures and layers 310; which are configured and arranged as shown. Generally, the FEOL structures and layers 304 are device elements (e.g., transistors, capacitors, resistors, etc.) patterned in the semiconductor substrate 302. The processes used to form the FEOL structures and layers 304 include wafer preparation; isolation; gate patterning; the formation of wells; the formation of source/drain (S/D) regions; the formation of extension junctions; the formation of silicide regions; and the formation of liners. The FEOL structures and layers 304 form the primary functional circuitry of the IC chip 212A. The process flows used to form the MOL structures and layers 306 can include forming interconnect structures (e.g., lines, wires, metal-filled vias, contacts, and the like) that communicatively couple to active regions (e.g., gate, source, and drain) of the device element. The processes used to form the BEOL structures and layers 308 include forming layers of interconnect structures above the logical and functional layers. To support the increased component density, a hierarchical wiring method can be applied in which multiple levels of interconnect wires are fabricated in a level-by-level scheme. In this situation, the BEOL structures and layers 308 can include a plurality of wiring levels to provide interconnections for the MOL structures and layers 306, and a set of Far-BEOL (FBEOL) structures and layers 310 can be provided that include metal layers (e.g., the under-bump-metal or redistribution layer) and associated interconnect structures that form the connection between on-chip and off-chip wiring connections. The photoresist layer 230 is formed over the Far-BEOL structures and layers 310 and hardened using a suitable photoresist hardening process, including but not limited to hardening processes that utilize exposure of the photoresist layer 230 to ultra-violet (UV) light and subsequent baking. In aspects of the invention, the photoresist layer 230 is made robust by providing the photoresist layer 230 with sufficient thickness D1 and hardening to withstand the sputter etch and directional RIE processes performed at blocks 106, 108.

The cross-sectional view shown in FIG. 3A depicts cross-sectional views of the chip separation trenches 220A that result from application of the sputter etch process 106 of the method 100. As shown, the sputter etch process of block 106 has been used form the chip separation trenches 220A through the various materials from which the Far-BEOL, BEOL, MOL, and/or FEOL structures/layers 304, 306, 308, 310 are formed (e.g., metals, dielectrics, doped semiconductor materials, etc.). The sputter etch process of block 106 is continued until a surface of the wafer substrate 302 is exposed at the bottom of the chip separation trenches 220A. It is anticipated that a small amount of the wafer substrate 302 may also be removed by the sputter etch process of block 106 prior to the directional reactive ion etch performed at block 108.

FIG. 3B depicts the cross-sectional view of the semiconductor wafer 200 shown in FIG. 3A, along with a diagram depicting a sputter etch process 302A that can be used to form the chip separation trenches 220A, 220B (shown in FIGS. 2 and 3A). In accordance with aspects of the invention, the sputter etch process 302A is a non-limiting example of how the sputter etch operation performed at block 106 of the method 100 can be implemented. As shown in FIG. 3B, the sputter etch process 302A can be implemented in a vacuum chamber 304. Within the chamber 304, a cathode electrode 306 is separated from a grounded anode electrode 308, and the wafer 200 with the photoresist layer 230 formed thereon is secured to the cathode electrode 306.

A pathway is provided for a plasma gas to enter and exit the vacuum chamber 304 under influence of a pumping action. The plasma gas carries highly energetic or ionized particles (e.g., argon). An electric field is created in the chamber 304 by applying a voltage to the cathode electrode 306 where the wafer 200 is secured. The ionized particles in the plasma gas are made to move very fast under the influence of the electric field. More specifically, the ions in the plasma gas are pulled toward the cathode electrode 306 and therefore onto the exposed surfaces of the photoresist 230 and surfaces of the wafer 200 that have been exposed or opened by the chip separation channel 220A. The ionized particles are pulled toward the cathode electrode 306 with energy (in electron volts) similar to the applied voltage. In accordance with embodiments of the invention, the voltage applied to the cathode electrode 106 is sufficiently high to provide the accelerated ionized particles with enough kinetic energy to allow them to dislodge atoms and sputter material of the exposed portions of the wafer 200 away. In embodiments of the invention, the ionized particles are argon ions, which have the technical benefit of being chemically inert, easily ionized, relatively inexpensive, and heavy ions that are effective for chipping away at a variety of materials, including specifically the various materials (e.g., metals, dielectrics, doped semiconductors, and the like) from which the Far-BEOL, BEOL, MOL, and FEOL structures and layers 304, 306, 308, 310 are formed. The sputter etch process 302A is particularly beneficial in that many of the materials used in the Far-BEOL, BEOL, MOL, and FEOL structures and layers 304, 306, 308, 310 (e.g., cobalt and/or copper wiring) are resistant to chemical etching. As previously noted herein, the photoresist layer 230 is made sufficiently robust by providing the photoresist layer 230 with sufficient thickness D1 and hardening (e.g., UV hardening followed by baking) to remain intact during the etch of the Far-BEOL, BEOL, MOL, and FEOL structures and layers 304, 306, 308, 310 by the sputter etch process 302A. The use of very small ionized atoms as the bombardment agent of the sputter etch process 302A makes the process 302A highly effective for etching the very fine resolution photoresist etch patterns 230A (shown in FIG. 3A), as well as for creating very smooth surfaces and perimeter edges of the channel separation trench 220A. The material or debris removed by the ionized particles is ejected from the wafer 200 (which is secured to the cathode electrode 306) to accumulate on the grounded anode electrode 308 or be removed from the exit of the chamber 304 by the chamber's gas pumping action.

FIG. 4A depicts a top-down view and a cross-sectional view of the semiconductor wafer 200 after applying an example of the directional RIE operations performed at block 108 of the method 100 according to embodiments of the invention. The top-down view of the wafer 200 shown in FIG. 4A is substantially the same as the top-down view of the wafer 200 shown in FIG. 3A except the directional RIE operation at block 108 of the method 100 has been used to etch through the exposed surface of the substrate 302 located at the bottom of the chip separation trenches 220A, 220B (shown in FIG. 3A) to form chip separation trenches 220A′, 220B′.

The cross-sectional view of the semiconductor wafer 200 shown in FIG. 4A is taken along line A-A of the top-down view shown in FIG. 4A. The cross-sectional view shown in FIG. 4A depicts cross-sectional views of the chip separation trench 220A′ that results from application of the directional RIE operations 108 of the method 100. As shown, the directional RIE operations of block 108 of the method 100 have been used form the chip separation trench 220A′ such that it extends into the wafer substrate 302, thereby forming sidewalls and some perimeter edges of an IC chip substrate 302A of the IC chip 212A. At the fabrication stage depicted in the cross-sectional view of FIG. 4A, the IC chip 212A is separated on all sides from the wafer 200 but is still connected to the wafer 200 at the interface between the IC chip substrate 302A and the wafer substrate 302. The directional RIE operations performed at block 108 of the method 100 are continued until a desired height dimension (D2) of the IC chip substrate 302A has been reached. The operations performed at block 108 have the additional benefit of creating very smooth surfaces and perimeter edges of the portion of the channel separation trench 220A′ that extends into the wafer substrate 302.

FIG. 4B depicts the cross-sectional view of the semiconductor wafer 200 shown in FIG. 4A, along with a diagram depicting a so-called Bosch deep RIE process 402A, which is a non-limiting example of how the directional RIE operations performed at block 108 of the method 100 can be implemented. The Bosch deep RIE process 402A is well-matched to embodiments of the invention where the wafer substrate 302 is silicon because Bosch deep RIE processes are efficient for etching high aspect ratio trench-type structures in silicon. In general, the process 402A includes a cyclic isotropic silicon etch and fluorocarbon-based protection film. The plasma etch gas for silicon is typically SF₆ and the protective layer plasma etch gas is typically C₄F₈. The directionality of the silicon etch removes the protective layer from only the bottom of the feature, while the sidewalls remain protected. The Bosch deep RIE process 402A is depicted in FIG. 4B as six (6) diagrams illustrating example operations of the process 402A applied to a silicon substrate, wherein the operations include exposing and hardening a resist over a silicon substrate; performing a first etch step; performing a first protective fluorocarbon layer deposition; performing a first removal of a bottom portion of the protective fluorocarbon layer; completing a second cycle of steps 2-4; and completing a third cycle of steps 2-4. In embodiments of the invention, the surfaces and perimeter edges of the IC chip substrate 302A that result from the process 402A each includes a roughness level that is less than about 4 μm Ra.

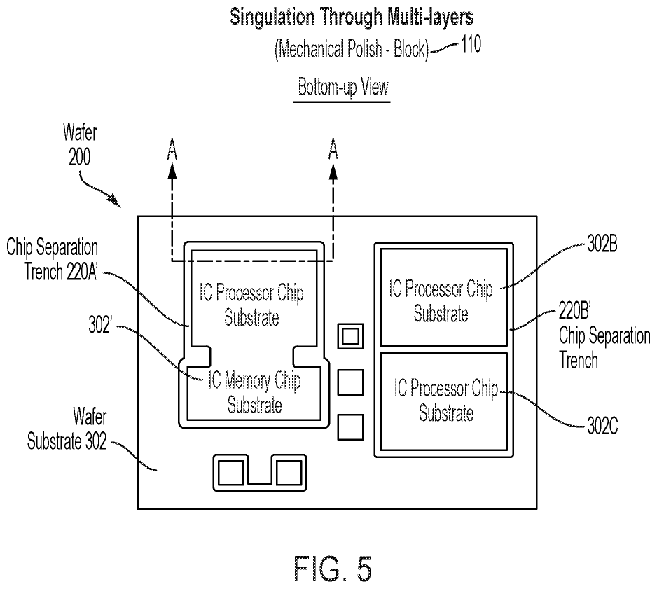

FIG. 5 depicts a bottom-up view and a cross-sectional view of the semiconductor wafer 200 after applying an example of the mechanical polishing operations performed at block 110 of the method 100 according to embodiments of the invention. The bottom-up view of the wafer 200 shows the chip separation trench 220A′; the chip separation trench 220B′; the IC processor chip substrate 302A; an IC memory chip substrate 302A′; an IC processor chip substrate 302B; and an IC processor chip substrate 302C. The bottom-up view of the wafer 200 shown in FIG. 5 is substantially the same as the top-down view of the wafer 200 shown in FIG. 4A except the mechanical polishing operation at block 110 of the method 100 has been used to remove a bottom portion of the wafer substrate 302, thereby separating bottom ends of the IC chip substrate 302A, 302A′, 302B, 302C from the wafer substrate 302 and singulating or removing the IC chips 212A, 214, 212B, 212C from the wafer 200. Similarly, the cross-sectional view of the wafer 200 shown in FIG. 5 is substantially the same as the cross-sectional view of the wafer 200 shown in FIG. 4B except the mechanical polishing operation at block 110 of the method 100 has been used to remove the bottom portion of the wafer substrate 302, thereby separating the bottom end of the IC chip substrate 302A from the wafer substrate 302 and singulating or removing the IC chip 212A from the wafer 200.

In embodiments of the invention, the mechanical polishing operations used at block 110 of the method 100 to remove the bottom end of the wafer substrate 302 can be performed using a polishing pad and a slurry. In some embodiments of the invention, a wax is applied to a front surface of the wafer 200, and the front surface of the wafer 200 is affixed through the wax to a holder. The polishing pad and a coarse slurry or grit can be used to uniformly erode the bottom end of the wafer substrate 302 until the bottom end of the wafer substrate 302 is within a predetermined distance of the bottom of the channel separation trench 220A′. The polishing pad is switched to a finer slurry/grit, and the remaining portion of the bottom end of the wafer substrate 302 is removed until the bottom of the channel separation trench 220A′ is met. In accordance with embodiments of the invention, the finer slurry/grip is configured to provide the bottom surface of the wafer substrate 302A with smooth perimeter edges. In embodiments of the invention, the surfaces and perimeter edges of the bottom surface of the IC chip substrate 302A that result from using the fine grit/slurry can each include a roughness level that is less than about 4 μm Ra.

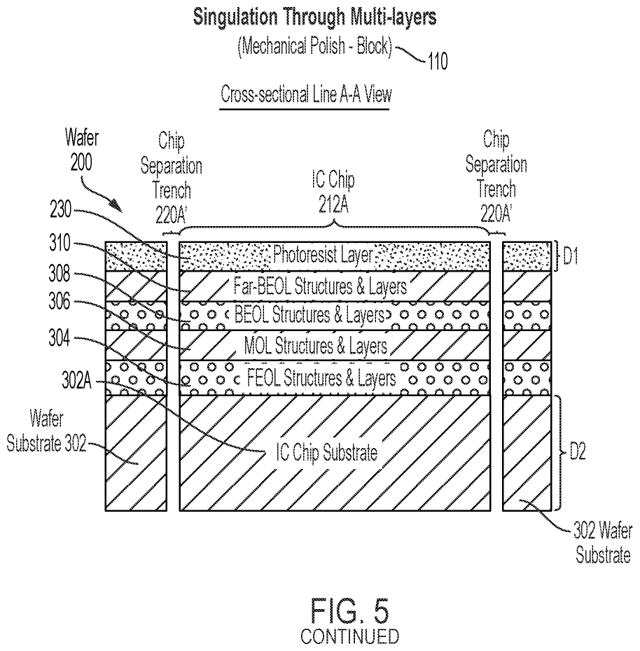

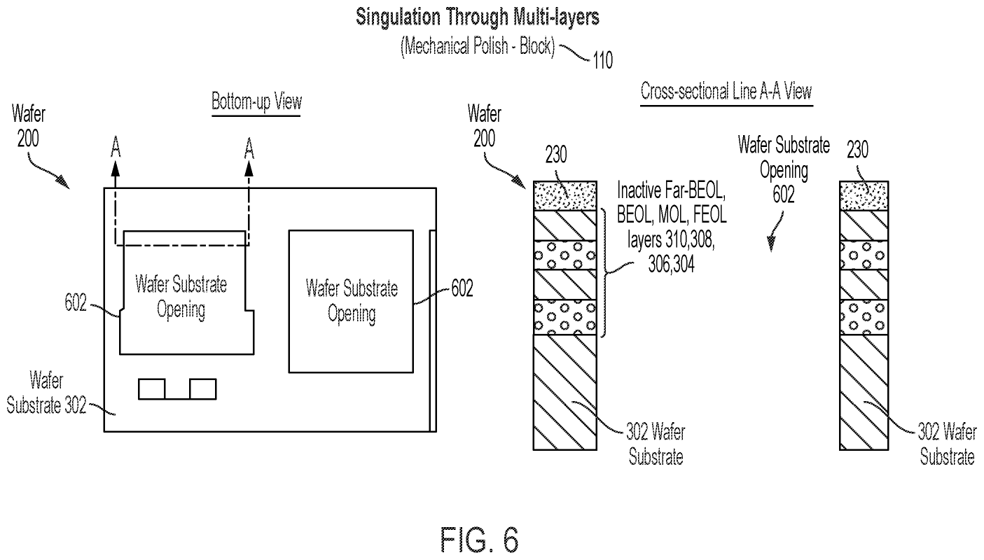

FIG. 6 depicts a bottom up and a cross-sectional view of the semiconductor wafer 200 after the mechanical polish operations 110 have singulated (or removed) the IC chips 212A, 214, 212B, 212C from the wafer 200, thereby leaving wafer substrate openings 602 in the wafer 200, configured and arranged as shown. The remaining post-singulation wafer 200 shown in FIG. 6 include regions of inactive Far-BEOL, BEOL, MOL, FEOL structures and layers 304, 306, 308, 310 formed over the post-polishing segments of the wafer substrate 302.

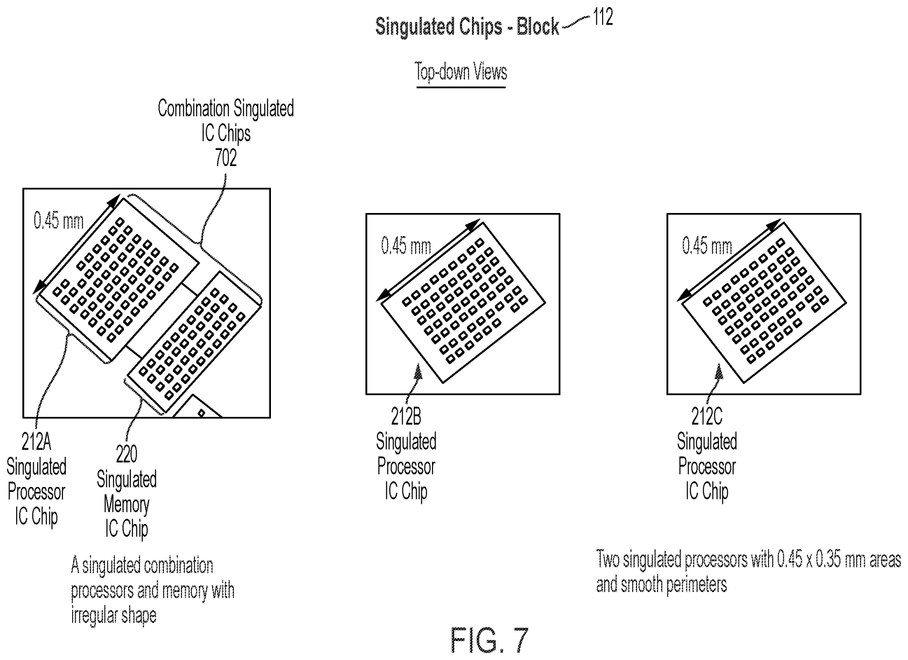

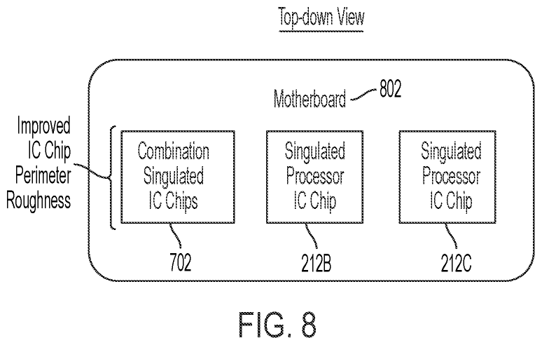

FIG. 7 depicts top-down views of the singulated IC chips 702 (formed from a combination of IC chips 212A, 214), 212B, 212C generated at block 112 of the method 100. In some non-limiting embodiments of the invention, the method 100 can be used to fabricate the irregularly shaped IC chip 702 having a width dimension of about 0.45 mm, along with two processor IC chips 212B, 212C each having a top surface area of about 0.45 mm by about 0.35 mm. The chip dimensions are examples and do not limit the scope of embodiments of the invention described herein. FIG. 8 depicts a top-down view of the singulated IC chips 702, 212B, 212C after an alignment tool has utilized the smooth perimeter edges of the singulated IC chips 702, 212B, 212C to achieve proper alignment of solder posts (not shown separately) on the IC chips 702, 212B, 212C with pads on the motherboard 802 as part of the final packaging operations. In embodiments of the invention, the surfaces and perimeter edges of the IC chips 702, 212B, 212C that result from the method 100 according to aspects of the invention can each include a roughness level that is less than about 4 μm Ra.

The polishing operation used to remove the first section of the remaining portion of the substrate that is underneath the first portion of the substrate is configured to form smooth edges during the polishing operation. The smooth perimeter edges formed during the etch operations and the polishing operations improve the functioning of packaging tools that the rely on automatic detection of the perimeter edges of the IC chip in order to accurately align the IC chip with its support substrate (e.g., a motherboard) during packaging. In embodiments of the invention, the sputter etch operations, the directional etch operations, and the polishing operations result in the singulated IC chips having very smooth perimeter edges having a roughness level that is less than about 4 μm Ra. The sputter etch is used to form a first segment of a separation trench, wherein the first segment of the separation trench separates the FEOL and BEOL layers that are part of the active regions of the IC chip from the FEOL and BEOL layers that are not part of the active regions of the IC chip. The sputter etch is a directional etch configured (e.g., through selection of the bombardment ions) to effectively etch through the multiple different types of materials (e.g., metals, dielectrics, doped semiconductors, etc.) in the FEOL and BEOL layers. The sputter etch also results in smooth surfaces and smooth perimeter edges within the first segment of the separation trench.

FIG. 9 depicts a block diagram illustrating semiconductor fabrication systems 900 that supports semiconductor fabrication processes capable of incorporating aspects of the invention. The semiconductor fabrication systems 900 includes IC design support algorithms 902, mask design support algorithms 904, manufacturing support equipment 906, assembly support equipment 908, and testing support equipment 910, configured and arranged as shown. The IC design support algorithms 902 are configured and arranged to provide computer-aided-design (CAD) assistance with the design of the logic circuits (AND, OR, and NOR gates) that form the various logic components of the IC. Similarly, the mask design support algorithms 904 are configured and arranged to provide CAD assistance with generating the mask design, which is the representation of an IC in terms of planar geometric shapes that correspond to the patterns of metal, oxide, or semiconductor layers that make up the components of the IC. The mask design places and connects all of the components that make up the IC such that they meet certain criteria, such as performance, size, density, and manufacturability. The manufacturing equipment 906 is the equipment used in executing the FEOL, MOL, BEOL, and Far-BEOL processes (including singulation processes) used to form the finished wafers and IC chips (or semiconductor die). In general, the wafer manufacturing equipment 906 come in various forms, most of which specialize in growing, depositing or removing materials from a wafer. Examples of wafer manufacturing equipment 906 include oxidation systems, epitaxial reactors, diffusion systems, ion implantation equipment, physical vapor deposition systems, chemical vapor deposition systems, photolithography equipment, etching equipment, polishing equipment and the like. The various types of manufacturing equipment 902 take turns in depositing and removing (e.g., using the chemicals 914) different materials on and from the wafer 912 in specific patterns until a circuit is completely built on the wafer 912. The assembly equipment 908 is used to package the IC chips into finished IC packages that are physically ready for use in customer applications. The assembly equipment 908 can include wafer back-grind systems, wafer saw equipment, die attach machines, wire-bonders, die overcoat systems, molding equipment, hermetic sealing equipment, metal can welders, DTFS (de-flash, trim, form, and singulation) machines, branding equipment, and lead finish equipment. The major components used by the assembly equipment 908 include but are not limited to lead frames 916 and substrates 918. The test equipment 910 is used to test the IC packages so that only known good devices will be shipped to customers. Test Equipment 910 can include automatic test equipment (ATE); test handlers; tape and reel equipment; marking equipment; burn-in ovens; retention bake ovens; UV (ultraviolet) erase equipment, and vacuum sealers.

Thus, it can be seen from the foregoing detailed description that embodiments of the invention provide technical effects and benefits. For example, the technical effects and benefits of the embodiments of the invention described herein include the use of patterned lithography and etch operations to form the separation trench, which enable the first separation trench to have shapes and feature resolution ranges (i.e., feature dimension ranges) that match the shapes and feature resolution ranges of the etch operations. In accordance with aspects of the invention, the patterned lithography and etch operations enable the formation of separation trenches having width dimension less than about 20 microns. In some embodiments of the invention, the patterned lithograph and etch operations enable the formation of separation trenches having width dimension between about 10 microns and about 20 microns. In embodiments of the invention, the patterned lithography and etch operations enable the formation of separation trenches having a wide variety of shapes, including but not limited to circles, squares, rectangles, hexagons, octagons, serpentine, and combinations thereof.

Additional technical effects and benefits of the embodiments of the invention described herein include the use of a sputter etch operations and directional RIE operations to form the separation trenches. The sputter etch operations are configured to remove the multiple different types of materials (e.g., metals, dielectrics, doped semiconductors, etc.) from which the FEOL and BEOL layers of the wafer can be formed. The sputter etch operations are also configured to form smooth edges during removal of the multiple different types of materials (e.g., metals, dielectrics, doped semiconductors, etc.) from which the FEOL and BEOL layers of the wafer can be formed. The directional RIE operations are configured to directionally remove selected segments of the semiconductor material (e.g., silicon) from which the substrate can be formed. The directional RIE operations are also configured to form smooth edges during removal of the semiconductor material (e.g., silicon) from which the substrate can be formed. The polishing operation used to remove selected portions of the substrate as the final singulation operation is configured to form smooth edges during the polishing operation. The smooth perimeter edges formed during the etch operations and the polishing operations improve the functioning of packaging tools that the rely on automatic detection of the perimeter edges of the IC chip in order to accurately align the IC chip with its support substrate (e.g., a motherboard) during packaging. In embodiments of the invention, the sputter etch operations, the directional etch operations, and the polishing operations result in the singulated IC chips having very smooth perimeter edges with a roughness level that is less than about 4 μm Ra.

Additional technical effects and benefits of the embodiments of the invention described herein include the sputter etch operation being applied in parallel to all of the IC chips on the host semiconductor wafer; the directional RIE operation being applied in parallel to all of the IC chips on the host semiconductor wafer; and the substrate polishing operation being applied to all of the IC chips on the host semiconductor wafer. Applying the etch operations and polishing operation across all of the IC chips on the host semiconductor in parallel improves efficiency and saves cost over known singulation operations that are applied in series to each IC chip on the host semiconductor wafer.

Additional technical effects and benefits of the above-described embodiments of the invention include the hardening process and the predetermined thickness improving a resistance of the photoresist layer to damage caused by the etch operations (e.g., sputtering etch and direction RIE) used to form the separation trenches.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

“Planarization” and “planarize” as used herein refer to a material removal process that employs at least mechanical forces, such as frictional media, to produce a substantially two-dimensional surface. A planarization process may include chemical mechanical polishing (CMP) or grinding. OH is a material removal process that uses both chemical reactions and mechanical forces to remove material and planarize a surface.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and in that manner the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method of singulating integrated circuit (IC) chips from a host semiconductor wafer, the method comprising;
receiving the host semiconductor wafer comprising a substrate and active layers formed over the substrate;
wherein the host semiconductor wafer further comprises a first IC chip comprising a first portion of the active layers and a first portion of the substrate;
forming a first separation trench by using an etch operation to remove a first segment of the active layers and a first segment of the substrate that are beneath a first separation channel of the host semiconductor wafer;
wherein the first separation trench separates:
the first portion of the active layers from a remaining portion of the active layers; and
the first portion of the substrate from a remaining portion of the substrate; and
singulating the first IC chip from the host semiconductor wafer by using a substrate removal operation to remove a first section of the remaining portion of the substrate that is underneath the first portion of the substrate.

2. The method of claim 1, wherein the first separation trench comprises a first segment and a second segment.

3. The method of claim 2, wherein the first segment of the first separation trench separates the first portion of the active layers from the remaining portion of the active layers.

4. The method of claim 3, wherein the second segment of the first separation trench separates the first portion of the substrate from the remaining portion of the substrate.

5. The method of claim 4, wherein the etch operation comprises:
a first etch operation configured to form the first segment of the first separation trench; and
a second etch operation configured to form the second segment of the first separation trench.

6. The method of claim 5, wherein:
the active layers comprise a front-end-of-line (FEOL) layer and a back-end-of-line (BEOL) layer;
the first etch operation comprises a sputter etch operation;
the second etch operation comprises a directional reactive ion etch operation; and
the substrate removal operation comprises polishing the first section of the remaining portion of the substrate that is underneath the first portion of the substrate.

7. The method of claim 1 further comprising:
the host semiconductor wafer further comprising a second IC chip comprising a second portion of the active layers and a second portion of the substrate;
forming a second separation trench by using the etch operation to, in parallel, remove:
a second segment of the active layers and a second segment of the substrate that are beneath a second separation channel of the host semiconductor wafer; and
the first segment of the active layers and the first segment of the substrate that are beneath the first separation channel of the host semiconductor wafer;
wherein the second separation trench separates:
the second portion of the active layers from the remaining portion of the active layers; and
the second portion of the substrate from the remaining portion of the substrate; and
singulating the second IC chip from the host semiconductor wafer by using the substrate removal operation to, in parallel, remove:
a second section of the remaining portion of the substrate that is underneath the second portion of the substrate; and
the first section of the remaining portion of the substrate that is underneath the first portion of the substrate.

8. A method of singulating integrated circuit (IC) chips from a host semiconductor wafer, the method comprising:
receiving the host semiconductor wafer comprising a substrate and active layers formed over the substrate;
wherein the host semiconductor wafer further comprises a first IC chip comprising a first portion of the active layers and a first portion of the substrate;
forming a photoresist layer on the host semiconductor wafer, wherein the photoresist layer defines a first separation channel of the host semiconductor wafer;
forming a first separation trench by using an etch operation to remove a first segment of the active layers and a first segment of the substrate that are beneath the first separation channel of the host semiconductor wafer;
wherein the first separation trench separates:
the first portion of the active layers from a remaining portion of the active layers; and
the first portion of the substrate from a remaining portion of the substrate; and
singulating the first IC chip from the host semiconductor wafer by using a substrate removal operation to remove a first section of the remaining portion of the substrate that is underneath the first portion of the substrate.

9. The method of claim 8, wherein the first separation trench comprises a first segment and a second segment.

10. The method o-f claim 9, wherein the first segment of the first separation trench separates the first portion of the active layers from the remaining portion of the active layers.

11. The method of claim 10, wherein the second segment of the first separation trench separates the first portion of the substrate from the remaining portion of the substrate.

12. The method of claim 11, wherein the etch operation comprises:
a first etch operation configured to form the first segment of the first separation trench; and
a second etch operation configured to form the second segment of the first separation trench.

13. The method of claim 12, wherein:
the active layers comprise a front-end-of-line (FEOL) layer and a back-end-of-line (BEOL) layer;
the first etch operation comprises a sputter etch operation;
the second etch operation comprises a directional reactive ion etch operation; and
the substrate removal operation comprises polishing the first section of the remaining portion of the substrate that is underneath the first portion of the substrate.

14. The method of claim 8 further comprising:
the host semiconductor wafer further comprising a second IC chip comprising a second portion of the active layers and a second portion of the substrate;
wherein the photoresist layer defines a second separation channel of the host semiconductor wafer;
forming a second separation trench by using the etch operation to, in parallel, remove:
a second segment of the active layers and a second segment of the substrate that are beneath a second separation channel of the host semiconductor wafer; and
a first segment of the active layers and a first segment of the substrate that are beneath a first separation channel of the host semiconductor wafer;
wherein the second separation trench separates:
the second portion of the active layers from the remaining portion of the active layers; and
the second portion of the substrate from the remaining portion of the substrate; and
singulating the second IC chip from the host semiconductor wafer by using the substrate removal operation to, in parallel, remove:
a second section of the remaining portion of the substrate that is underneath the second portion of the substrate; and
the first section of the remaining portion of the substrate that is underneath the first portion of the substrate.

15. A method of singulating integrated circuit (IC) chips from a host semiconductor wafer, the method comprising:
receiving the host semiconductor wafer comprising a substrate and active layers formed over the substrate;
wherein the host semiconductor wafer further comprises a first IC chip comprising a first portion of the active layers and a first portion of the substrate;
forming a photoresist layer having a predetermined thickness on the host semiconductor wafer, wherein the photoresist layer defines a first separation channel of the host semiconductor wafer;
applying a hardening process to the photoresist layer;
forming a first separation trench by using an etch operation to remove a first segment of the active layers and a first segment of the substrate that are beneath the first separation channel of the host semiconductor wafer;
wherein the first separation trench separates:
the first portion of the active layers from a remaining portion of the active layers; and
the first portion of the substrate from a remaining portion of the substrate; and
singulating the first IC chip from the host semiconductor wafer by using a polishing operation to remove a first section of the remaining portion of the substrate that is underneath the first portion of the substrate;
wherein the hardening process and the predetermined thickness improve a resistance of the photoresist layer to damage caused by the etch operation used to remove the first segment of the active layers and the first segment of the substrate that are beneath the first separation channel of the host semiconductor wafer.

16. The method of claim 15, wherein the first separation trench comprises a first segment and a second segment.

17. The method of claim 16, wherein the first segment of the first separation trench separates the first portion of the active layers from the remaining portion of the active layers.

18. The method of claim 17, wherein the second segment of the first separation trench separates the first portion of the substrate from the remaining portion of the substrate.

19. The method of claim 18, wherein the etch operation comprises:
a first etch operation configured to form the first segment of the first separation trench; and
a second etch operation configured to form the second segment of the first separation trench.

20. The method of claim 19, wherein:
the active layers comprise a front-end-of-line (FEOL) layer and a back-end-of-line (BEOL) layer;
the first etch operation comprises a sputter etch operation; and
the second etch operation comprises a directional reactive ion etch operation.

21. The method of claim 15 further comprising:
the host semiconductor wafer further comprising a second IC chip comprising a second portion of the active layers and a second portion of the substrate;
wherein the photoresist layer defines a second separation channel of the host semiconductor wafer;
forming a second separation trench by using the etch operation to, in parallel, remove:
a second segment of the active layers and a second segment of the substrate that are beneath a second separation channel of the host semiconductor wafer; and
a first segment of the active layers and a first segment of the substrate that are beneath a first separation channel of the host semiconductor wafer;
wherein the second separation trench separates:
the second portion of the active layers from the remaining portion of the active layers; and
the second portion of the substrate from the remaining portion of the substrate; and
singulating the second IC chip from the host semiconductor wafer by using the substrate removal operation to, in parallel, remove:
a second section of the remaining portion of the substrate that is underneath the second portion of the substrate; and
the first section of the remaining portion of the substrate that is underneath the first portion of the substrate.

22. A system for singulating integrated circuit (IC) chips from a host semiconductor wafer, the system comprising a configuration of semiconductor fabrication equipment configured to perform singulation operations comprising;
receiving the host semiconductor wafer comprising a substrate and active layers formed over the substrate;
wherein the host semiconductor wafer further comprises a first IC chip comprising a first portion of the active layers and a first portion of the substrate;
forming a first separation trench by using an etch operation to remove a first segment of the active layers and a first segment of the substrate that are beneath a first separation channel of the host semiconductor wafer;
wherein the first separation trench separates:
the first portion of the active layers from a remaining portion of the active layers; and
the first portion of the substrate from a remaining portion of the substrate; and
singulating the first IC chip from the host semiconductor wafer by using a substrate removal operation to remove a first section of the remaining portion of the substrate that is underneath the first portion of the substrate.

23. The system of claim 22, wherein:
the first separation trench comprises a first segment and a second segment;
the first segment of the first separation trench separates the first portion of the active layers from the remaining portion of the active layers;
the second segment of the first separation trench separates the first portion of the substrate from the remaining portion of the substrate;
the etch operation comprises a first etch operation configured to form the first segment of the first separation trench;
the etch operation further comprises a second etch operation configured to form the second segment of the first separation trench;
the active layers comprise a front-end-of-line (FEOL) layer and a back-end-of-line (BEOL) layer;
the first etch operation comprises a sputter etch operation;
the second etch operation comprises a directional reactive ion etch operation;
the substrate removal operation comprises polishing the first section of the remaining portion of the substrate that is underneath the first portion of the substrate;
the singulation operations further comprising:
the host semiconductor wafer further comprising a second IC chip comprising a second portion of the active layers and a second portion of the substrate;
forming a second separation trench by using the etch operation to, in parallel, remove:
a second segment of the active layers and a second segment of the substrate that are beneath a second separation channel of the host semiconductor wafer; and
a first segment of the active layers and a first segment of the substrate that are beneath a first separation channel of the host semiconductor wafer;
wherein the second separation trench separates:
the second portion of the active layers from the remaining portion of the active layers; and
the second portion of the substrate from the remaining portion of the substrate; and
singulating the second IC chip from the host semiconductor wafer by using the substrate removal operation to, in parallel, remove:
a second section of the remaining portion of the substrate that is underneath the second portion of the substrate; and
the first section of the remaining portion of the substrate that is underneath the first portion of the substrate.

24. A system for singulating integrated circuit (IC) chips from a host semiconductor wafer, the system comprising a configuration of semiconductor fabrication equipment configured to perform singulation operations comprising;
receiving the host semiconductor wafer comprising a substrate and active layers formed over the substrate;
wherein the host semiconductor wafer further comprises a first IC chip comprising a first portion of the active layers and a first portion of the substrate;
forming a photoresist layer on the host semiconductor wafer, wherein the photoresist layer defines a first separation channel of the host semiconductor wafer;
forming a first separation trench by using an etch operation to remove a first segment of the active layers and a first segment of the substrate that are beneath the first separation channel of the host semiconductor wafer;
wherein the first separation trench separates:
the first portion of the active layers from a remaining portion of the active layers; and
the first portion of the substrate from a remaining portion of the substrate; and
singulating the first IC chip from the host semiconductor wafer by using a substrate removal operation to remove a first section of the remaining portion of the substrate that is underneath the first portion of the substrate.

25. The system of claim 24, wherein:
the first separation trench comprises a first segment and a second segment;
the first segment of the first separation trench separates the first portion of the active layers from the remaining portion of the active layers;
the second segment of the first separation trench separates the first portion of the substrate from the remaining portion of the substrate;
the etch operation comprises:
a first etch operation configured to form the first segment of the first separation trench; and
a second etch operation configured to form the second segment of the first separation trench;
the first etch operation comprises a sputter etch operation;
the active layers comprise a front-end-of-line (FEOL) layer and a back-end-of-line (BEOL) layer;
the second etch operation comprises a directional reactive ion etch operation;
the substrate removal operation comprises polishing the first section of the remaining portion of the substrate that is underneath the first portion of the substrate;
the host semiconductor wafer further comprising a second IC chip comprising a second portion of the active layers and a second portion of the substrate;
the photoresist layer defining a second separation channel of the host semiconductor wafer;
forming a second separation trench by using the etch operation to, in parallel, remove:
a second segment of the active layers and a second segment of the substrate that are beneath a second separation channel of the host semiconductor wafer; and
a first segment of the active layers and a first segment of the substrate that are beneath a first separation channel of the host semiconductor wafer;
the second separation trench separating:
the second portion of the active layers from the remaining portion of the active layers; and
the second portion of the substrate from the remaining portion of the substrate; and
singulating the second IC chip from the host semiconductor wafer by using the substrate removal operation to, in parallel, remove:
a second section of the remaining portion of the substrate that is underneath the second portion of the substrate; and
the first section of the remaining portion of the substrate that is underneath the first portion of the substrate.
